(19) United States
(12) Patent Application Publication
(10) Pub. No.: US 2015/0364562 A1
(43) Pub. Date: Dec. 17, 2015

(54) SEMICONDUCTOR DEVICE

(71) Applicant: Kabushiki Kaisha Toshiba, Tokyo (JP)

(72) Inventors: Yoshitaka Hokomoto, Kanazawa Ishikawa (JP); Tatsuya Nishiwaki, Komatsu Ishikawa (JP); Masatoshi Arai, Hakusan Ishikawa (JP)

(21) Appl. No.: 14/641,230

(22) Filed: Mar. 6, 2015

(30) Foreign Application Priority Data
Jun. 14, 2014 (JP) 2014-122936

(51) Int. Cl. H01L 29/47; H01L 29/812; H01L 29/66; H01L 29/423

(52) U.S. Cl. CPC H01L 29/47; H01L 29/4236; H01L 29/812; H01L 29/66848

(57) ABSTRACT

A semiconductor device includes a first semiconductor layer that includes a first region and a second region, a second semiconductor layer that is provided on an upper side of the first semiconductor layer, a third semiconductor layer that is selectively provided on an upper side of the second semiconductor layer, a control electrode provided in the second semiconductor layer and the third semiconductor layer through an insulation film, a first conductor that is provided in the first semiconductor layer so as to be in contact with the control electrode and the first semiconductor layer through the insulation film and is positioned further on a first semiconductor layer side than the control electrode, a second conductor that extends in a direction from the third semiconductor layer to the first semiconductor layer in the second region and is provided in the first semiconductor layer through an insulation film, a first electrode that is electrically connected to the first semiconductor layer, the second semiconductor layer, and the third semiconductor layer, and a second electrode that is electrically connected to the first semiconductor layer.

### CROSS-REFERENCE TO RELATED APPLICATION

This application is based upon and claims the benefit of priority from the prior Japanese Patent Application No. 2014-122936, filed Jun. 14, 2014, the entire contents of which are incorporated herein by reference.

### FIELD

Embodiments described herein relate generally to a semiconductor device.

### BACKGROUND

In general, a Metal Oxide Semiconductor Field Effective Transistor (MOSFET) is used as a switching element in a power supply circuit, a DC-AC converter, a DC-DC converter, and the like. The switching element is divided into a high-side MOSFET whose drain is connected to a power supply terminal, and a low-side MOSFET whose source is grounded. For example, in the DC-DC converter, the source of the high-side MOSFET and a drain of the low-side MOSFET are connected to each other in series. The high-side MOSFET and the low-side MOSFET are repeatedly turned on and off by turns, and thereby a voltage of a short shape is output. After the high-side MOSFET is turned off, a back electromotive force is exerted by an inductance component that is included in a load, a wiring, or the like while the low-side MOSFET is turned on. A current that is generated by the back electromotive force flows in the parasitic pn diode of the low-side MOSFET in the forward direction. However, since a resistance value is high in the parasitic pn diode, power loss is high. Therefore, it is known to form a schottky barrier diode causing a low power loss in low-side MOSFET. This type of schottky barrier diode is provided in parallel with the MOSFET on the same substrate so as to reduce a wiring connection between the MOSFET and the schottky barrier diode and to reduce the inductance component. However, a SBD which is a schottky bonding has a lower breakdown voltage than the MOSFET, thereby causing a breakdown at a low reverse voltage. Therefore, if a reverse voltage is applied when the SBD and the MOSFET are formed on the same plane, it is not possible to sufficiently have a breakdown voltage.

### BRIEF DESCRIPTION OF THE DRAWINGS

FIG. 1 is a schematic diagram of a DC-DC converter according to a first embodiment.

FIG. 2 is a schematic plan view of a semiconductor device according to the first embodiment.

FIG. 3 is a cross-sectional view of the semiconductor device taken along line Ia-Ia illustrated in FIG. 2.

FIG. 4 is a cross-sectional view of the semiconductor device in a manufacturing process of the semiconductor device according to the first embodiment.

FIG. 5 is a cross-sectional view of the semiconductor device in the manufacturing process of the semiconductor device according to the first embodiment.

FIG. 6 is a cross-sectional view of the semiconductor device in the manufacturing process of the semiconductor device according to the first embodiment.

FIG. 7 is a cross-sectional view of the semiconductor device in the manufacturing process of the semiconductor device according to the first embodiment.

FIG. 8 is a cross-sectional view of the semiconductor device in the manufacturing process of the semiconductor device according to the first embodiment.

FIG. 9 is a cross-sectional view of the semiconductor device in the manufacturing process of the semiconductor device according to the first embodiment.

FIG. 10 is a cross-sectional view of the semiconductor device in the manufacturing process of the semiconductor device according to the first embodiment.

FIG. 11 is a cross-sectional view of the semiconductor device in the manufacturing process of the semiconductor device according to the first embodiment.

### DETAILED DESCRIPTION

In general, according to one embodiment, a semiconductor device includes: a first semiconductor layer of a first conductivity type that includes a first region and a second region adjacent to the first region; a second semiconductor layer of a second conductivity type that is provided on an upper side of the first semiconductor layer in the first region; a third semiconductor layer of the first conductivity type that is selectively provided on an upper side of the second semiconductor layer; a control electrode that is provided in the second semiconductor layer and the third semiconductor layer through an insulation film; a first conductor that is provided in the first semiconductor layer so as to be in contact with the control electrode and the first semiconductor layer through the insulation film and is positioned further on a first semiconductor layer side than the control electrode; a second conductor that extends in a direction from the third semiconductor layer to the first semiconductor layer in the second region and is provided in the first semiconductor layer through an insulation film; a first electrode that is electrically connected to the first semiconductor layer, the second semiconductor layer, and the third semiconductor layer; and a second electrode that is electrically connected to the first semiconductor layer.

In general, according to another embodiment, a method of manufacturing a semiconductor device includes: forming a first semiconductor layer of a first conductivity type that includes a first region and a second region; forming a second semiconductor layer of a second conductivity type on an upper side of the first semiconductor layer in the first region; forming selectively a third semiconductor layer of the first conductivity type on an upper side of the second semiconductor layer; forming simultaneously a first trench that is in contact with the first semiconductor layer, the second semiconductor layer and the third semiconductor layer in the first region, and a second trench that is provided in the second region; forming a control electrode that is positioned in the first trench in the second semiconductor layer and the third semiconductor layer through an insulation film; forming a first conductor that is positioned further on the first semiconductor layer side than the control electrode and is formed in the first trench in the first semiconductor layer through the insulation film; forming a second conductor film in the second trench through an insulation film; forming a first electrode so as to be electrically connected to the first semiconductor layer, the second semiconductor layer, and the third semiconductor layer; and forming a second electrode so as to be electrically connected to the first semiconductor layer.

Hereinafter, the embodiment will be described with reference to drawings. Description in detail is appropriately omitted by applying like reference numerals to the like elements in each drawing. Moreover, description will be made with an assumption that an n type is a first conductivity type, and a p type is a second conductivity type; however, the embodiment may be implemented even if the p type is set as the first conductivity type and the n type is set as the second conductivity type.

### First Embodiment

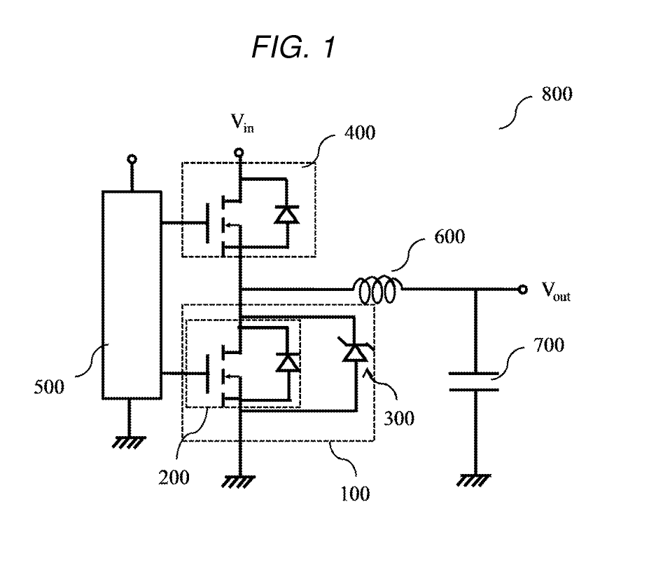

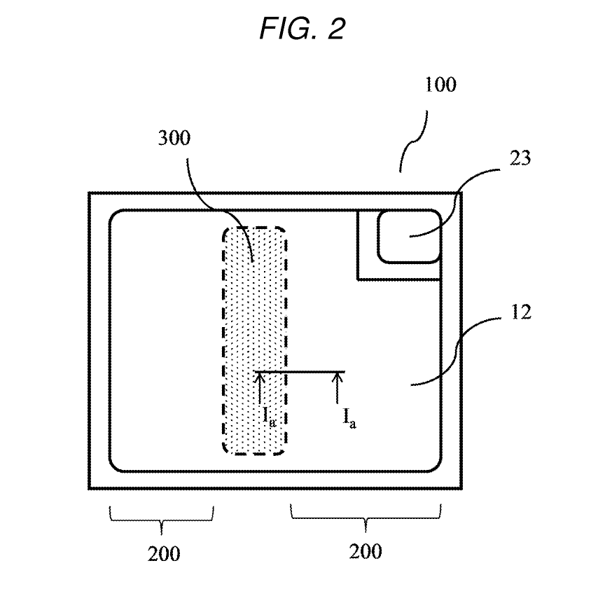

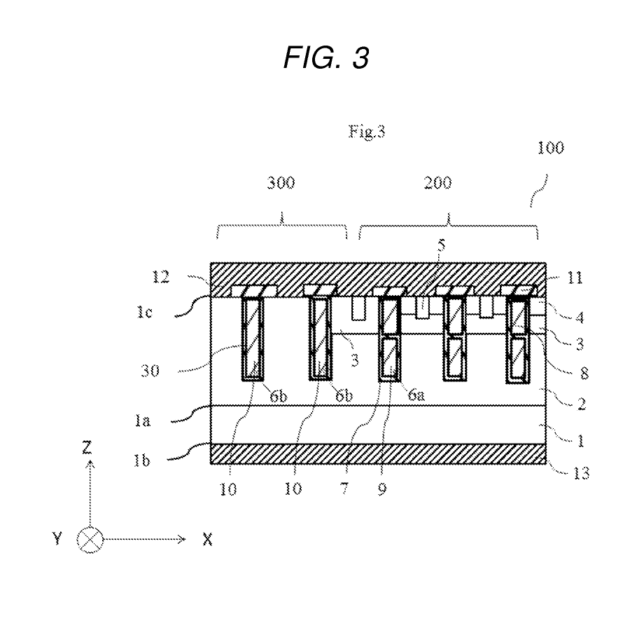

A semiconductor device according to a first embodiment will be described with reference to FIGS. 1 to 3. FIG. 1 is a schematic diagram of a DC-DC converter according to the first embodiment. FIG. 2 is a schematic plan view which illustrates the semiconductor device according to the first embodiment. FIG. 3 is a cross-sectional view of the semiconductor device taken along line Ia-Ia illustrated in FIG. 2.

FIG. 1 is a schematic diagram of a DC-DC converter according to the first embodiment.

A DC-DC converter 800 as illustrated in FIG. 1 includes a semiconductor device 100, a semiconductor device 400, a controller 500, an inductor 600, and a capacitance element 700. The semiconductor device 100 includes a low-side MOSFET and a schottky barrier diode (SBD), and the semiconductor device 400 is a high-side MOSFET. The semiconductor device 100 and the semiconductor device 400 are switching elements of the DC-DC converter 800. The controller 500 controls an ON/OFF operation of the semiconductor device 100 and the semiconductor device 400.

The semiconductor device 100 of the embodiment includes the low-side MOSFET and the schottky barrier diode (SBD) in the DC-DC converter 800 in FIG. 1 on the same substrate.

The semiconductor device 100 according to the embodiment is configured to have a semiconductor substrate 1, an n-type drift layer 2, a p-type base layer 3, an n⁺-type source layer 4, a p⁺-type contact layer 5, a first insulation film 7, a gate electrode 8, a first field plate electrode 9, a second field plate electrode 10, an insulation film 11, a first electrode 12, a second electrode 13, a second insulation film 30 and the like.

As illustrated in FIG. 2, in the semiconductor device 100, a region including a MOSFET is referred to as a MOSFET region 200 (first region), and a region including a schottky barrier diode (SBD) is referred to as a SBD region 300 (second region).

The semiconductor substrate 1 made of silicon has a first surface 1a, and a second surface 1b facing the first surface 1a. The semiconductor substrate 1 is an n-type semiconductor region which has an impurity such as phosphorus, arsenic, or the like. The n-type impurity concentration is, for example, 1×10¹⁹ cm⁻³ to 1×10²⁰ cm⁻³.

As illustrated in FIG. 3, the n-type drift layer 2 (first semiconductor layer) is provided on the first surface 1a. The n-type drift layer 2 has a third surface 1c and is opposed to the third surface 1c. The n-type drift layer 2 is a layer which holds a breakdown voltage in the semiconductor device 100. An n-type impurity concentration of the n-type drift layer 2 is, for example, 3×10¹⁶ cm⁻³ to 1×10¹⁷ cm⁻³.

Here, one of directions in parallel with the third surface 1c is set to be an X direction, a direction which is also in parallel with the third surface 1c and is orthogonal to the X direction is set to be a Y direction, and a direction which is orthogonal to the X and Y directions and is from the semiconductor substrate 1 toward the third surface 1c is set to be a Z direction. In a depth direction (Z direction) of the semiconductor device 100, an impurity concentration of the n-type drift layer 2 may be constant, but may be high in a vicinity of an interface between the semiconductor substrate 1 and the n-type drift layer 2. Accordingly, it is possible to reduce a contact resistance at the interface between the semiconductor substrate 1 and the n-type drift layer 2, and to reduce an on-resistance of the semiconductor device 100. A thickness of the n-type drift layer 2 in the Z direction is, for example, about 3 μm to 5 μm.

The p-type base layer 3 (second semiconductor layer) is provided on the n-type drift layer 2. When a voltage equal to or greater than a threshold value is applied to the gate electrode 8, an n-type inversion layer is formed in the p-type base layer 3. The gate electrode 8 will be described in detail below. The p-type base layer 3 is a p-type semiconductor region which has an impurity such as boron (B) and the like. A p-type impurity concentration of the p-type base layer 3 is, for example, 1×10¹⁶ cm⁻³ to 1×10¹⁸ cm⁻³. The p-type impurity concentration of the p-type base layer 3 tends to be low in a vicinity of an interface between the p-type base layer 3 and the n-type drift layer 2, but tends to be increased as distance from the n-type drift layer 2 increases. A thickness of the p-type base layer 3 in the Z direction is, for example, about 0.5 μm to 1 μm.

In the MOSFET region 200, a trench 6a extends in the Z direction, one terminal thereof is positioned on the third surface 1c, and the other terminal is positioned in the n-type drift layer 2. In addition, the trenches 6a are provided at regular intervals in the X direction so as to extend in the Y direction. The trench 6a is formed using a lithography technique and an etching technique.

In the SBD region 300, trenches 6b are provided in the n-type drift layer 2 so as to extend from the third surface 1c toward the semiconductor substrate 1. The trenches 6b are provided at regular intervals in the X direction so as to extend in the Y direction. In addition, positions (depth) of bottom surfaces of the trenches 6b in the Z direction are substantially the same as positions of bottom surfaces of the trenches 6a. That is, bottom portions of the trench 6b are positioned further on the semiconductor substrate 1 side than the p-type base layer 3. The trenches 6b are formed using a lithography technique and an etching technique.

An interval between the trench 6a and the trench 6b is substantially constant. For example, an interval between the trench 6a and the trench 6b is about 1 μm to 2 μm. In addition, a width (length in the X direction) of the trench 6a and the trench 6b is, for example, about 0.1 μm to 0.5 μm.

The gate electrode 8 (second conductor) is provided in the trench 6a so as to be in contact with the p-type base layer 3 through the first insulation film 7. The gate electrode 8 extends in the Y direction, and is electrically connected to a gate wiring electrode 23 provided at an end of the semiconductor device 100 and the like.

The first field plate electrode 9 (first conductor) which is positioned further on the semiconductor substrate 1 side than the gate electrode 8 is provided in the trench 6a so as to be in contact with the n-type drift layer 2 through the first insulation film 7. The first field plate electrode 9 extends in the Y direction, and is electrically connected to the end of the semiconductor device 100 so as to have the same potential as another first field plate electrode 9. The first field plate electrode 9 forms a depletion layer in the n-type drift layer 2 when a voltage applied to the gate electrode 8 is equal to or less than a threshold value.

The second field plate electrode 10 (third conductor) is provided in the trench 6b so as to be in contact with the n-type drift layer 2 through the second insulation film 30. The second field plate electrode 10 extends in the Y direction in the same manner as the first field plate electrode 9, and is electrically connected to an end of the semiconductor device 100 so as to have the same potential as another second field plate electrode 10. The second field plate electrode 10 forms a depletion layer in the n-type drift layer 2 in the SBD region 300 when a reverse voltage at which the first electrode 12 has a lower potential than the second electrode 13 is applied.

The gate electrode 8, the first field plate electrode 9, and the second field plate electrode 10 are formed of silicon oxide (SiO₂), polysilicon, or the like. SiO₂ or polysilicon is formed by, for example, a Chemical Vapor Deposition (CVD) method.

In the MOSFET region 200, the n⁺-type source layer 4 is selectively provided on the p-type base layer 3. The n⁺-type source layer 4 in the X direction is in contact with the first insulation film 7 (side surface of the trench 6a). The n⁺-type source layer 4 functions as a source region which supplies an electron when an inversion layer is formed in the p-type base layer 3. An n-type impurity concentration of the n⁺-type source layer 4 is, for example, 1×10¹⁹ cm⁻³ to 1×10²⁰ cm⁻³. A thickness of the n⁺-type source layer 4 in the Z direction is, for example, about 0.2 μm to 0.7 μm.

In the MOSFET region 200, a p⁺-type contact layer 5 (third semiconductor layer) is provided on the p-type base layer 3. The p⁺-type contact layer 5 is positioned between adjacent n⁺-type source layers 4 and is provided being in contact with the n⁺-type source layer 4. A p-type impurity concentration of the p⁺-type contact layer 5 is, for example, 1×10¹⁹ cm⁻³ to 1×10²⁰ cm⁻³.

The insulation film 11 is provided on the third surface 1c so as to be in contact with the p-type base layer 3, an n⁺-type source layer 4, the first field plate electrode 9 through the first insulation film 7, and the second field plate electrode 10 through the second insulation film 30. The insulation film 11 is an oxide film such as Tetraethyl orthosilicate (TEOS) and the like, and is formed by a plasma CVD method.

The first electrode 12 is provided on the third surface 1c and the insulation film 11, and is electrically connected to the n-type drift layer 2, the n⁺-type source layer 4, and the p⁺-type contact layer 5.

In the MOSFET region 200, the first electrode 12 has a function of a source electrode. In the SBD region 300, a connected portion between the first electrode 12 and the n-type drift layer 2 is a schottky junction. The first electrode 12 has a function of an anode electrode in the SBD region 300.

The second electrode 13 is provided on the second surface 1b. The second electrode 13 is electrically connected to the semiconductor substrate 1. The second electrode 13 has a function of a drain electrode in the MOSFET region 200, and a function of a cathode electrode in the SBD region 300.

The operations and effects of the semiconductor device 100 according to this embodiment when MOSFET is in an on state and when MOSFET is in an off state will be described, respectively.

The MOSFET is in an on state when a higher voltage is applied to a second electrode 13 which is a drain electrode than the first electrode 12 which is a source electrode, and a voltage applied to the gate electrode 8 is higher than a threshold voltage. At this time, the p-type base layer 3 becomes a source potential through the p⁺-type contact layer 5, and the n-type drift layer 2 becomes a drain potential. When in this state, in the p-type base layer 3 near the gate electrode 8, electrons which are minority carriers of the p-type base layer 3 are drawn into the gate electrode 8. Accordingly, an n-type inversion layer (not illustrated) is formed in the p-type base layer 3 through the first insulation film 7. The inversion layer functions as a channel. The electrons flow to the second electrode 13 from the first electrode 12 through the n⁺-type source layer 4, the n-type inversion layer formed in the p-type base layer 3, the n-type drift layer 2 and the semiconductor substrate 1. That is, a current flows from the second electrode 13 to the first electrode 12.

On the other hand, the MOSFET is in an off state when a voltage applied to the gate electrode 8 is lower than a threshold voltage. Accordingly, an n-type inversion layer formed in the p-type base layer 3 is disappeared, and a depletion layer is formed through the first insulation film 7 in the p-type base layer 3. Since a channel is not formed in the p-type base layer 3, a supply of electrons from the first electrode 12 becomes excessive. As a result, a voltage is applied to the n-type drift layer 2 and the p-type base layer 3 in a reverse direction. In a state where the reverse voltage is applied, a depletion layer is formed on a bonding surface of the n-type drift layer 2 and the p-type base layer 3. Since an impurity concentration of the n-type drift layer 2 is lower than an impurity concentration of the p-type base layer 3, the depletion layer extends toward the n-type drift layer 2.

The first field plate electrode 9 is a source potential as described above. Therefore, charges are attracted through the first insulation film 7 into the n-type drift layer 2 in which a first field plate electrode 9 is positioned, whereby the depletion layer is formed therein. The depletion layer extends in the X direction in a side surface of the first field plate electrode 9. In addition, the depletion layer extends from the third surface 1c to the semiconductor substrate 1 in a bottom surface of the first field plate electrode 9. The depletion layer extending in the X direction from both sides of the adjacent first field plate electrodes 9 and the depletion layer formed on the bonding surface of the n-type drift layer 2 and the p-type base layer 3 are bonded to each other. That is, the depletion layer is positioned in a range which is wider at a lower side of a direction from the third surface 1c to the semiconductor substrate 1 than the first field plate electrode 9 in the n-type drift layer 2 of the MOSFET region 200. Therefore, it is possible to have a high breakdown voltage in the MOSFET region 200.

In the SBD region 300, the depletion layer is formed in the n-type drift layer 2 in which the second field plate electrode 10 is positioned through the second insulation film 30. Except when a potential is reversed by the back electromotive force, the depletion layer is formed in the SBD in any case of on and off states. The depletion layer extends in the X direction from a side surface of the second field plate electrode 10, and extends in a direction from a bottom surface of the second field plate electrode 10 to the semiconductor substrate 1. At this time, adjacent depletion layers extending in the X direction from the side surface of the second field plate electrode 10 are bonded. Accordingly, the depletion layer is formed entirely on the n-type drift layer 2 of the SBD region 300.

Furthermore, when the MOSFET is in an off state, a depletion layer formed in the n-type drift layer 2 by the first field plate electrode 9 is bonded to a depletion layer formed in the n-type drift layer 2 by the second field plate electrode 10. Accordingly, since the depletion layer is spread over a wide range of the n-type drift layer 2, it is possible to fully secure a breakdown voltage in the MOSFET region 200 and the SBD region 300. As described above, it is possible to improve the breakdown voltage of the semiconductor device 100 in which the MOSFET region 200 and the SBD region 300 are formed on the same substrate.

Here, a switch conversion of the semiconductor device 100 and the semiconductor device 400 which are switching elements, that is, a state conversion from an on state to an off state, will be described in detail. When a high-side semiconductor device 400 is in an off state and a low-side semiconductor device 100 is in an on state, aback electromotive force occurs by an inductance component such as load, wiring, or the like. Potentials of the first electrode 12 which is an anode electrode and a source electrode and the second electrode 13 which is a cathode electrode and a drain electrode are instantaneously reversed by the back electromotive force in some cases. That is, since a higher voltage is applied to the first electrode 12 than the second electrode 13, a current flows from the first electrode 12 to the second electrode 13. At this time, a current flows in the SBD which has low resistance against a parasitic pn diode.

Accordingly, in a state where a forward voltage is instantaneously applied, it is possible to allow a forward current to flow in the SBD at a low voltage. On the other hand, in a state where a reverse voltage is applied, since the depletion layer is formed in the SBD having a low breakdown voltage, the depletion layer has a breakdown voltage without causing a breakdown. Accordingly, since SBD does not cause a breakdown even when a reverse voltage is applied to the SBD in the same manner as MOSFET, it is possible to improve a breakdown voltage of the MOSFET and the SBD which are formed on the same substrate.

In addition, since a bonding capacity between the first electrode 12 and the second electrode 13 is reduced as the depletion layer formed in the n-type drift layer 2 increases in size, an entire capacity of the semiconductor device 100 is reduced. Accordingly, the semiconductor device 100 may perform a high speed switching operation.

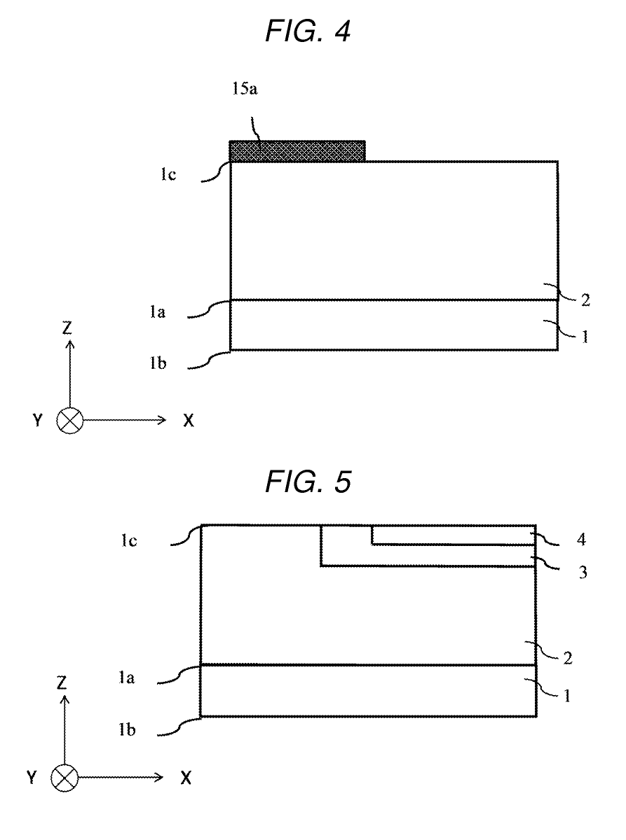

Next, a method of manufacturing the semiconductor device 100 according to the embodiment will be described using FIGS. 4 to 11. FIGS. 4 to 11 are cross-sectional views of a semiconductor device in a manufacturing process of the semiconductor device according to the first embodiment.

As illustrated in FIG. 4, a pattern is formed by applying a photoresist 15a on the n-type drift layer 2, and performing exposure and development.

As illustrated in FIG. 5, the p-type base layer 3 and the n⁺-type source layer 4 are sequentially formed in the n-type drift layer 2 by, for example, an ion implantation method from an exposed portion of the n-type drift layer 2. For example, boron (B) and the like are implanted into the p-type base layer 3, and phosphorus (P) or arsenic (As) is implanted into the n⁺-type source layer 4. When forming the p-type base layer 3, the n⁺-type source layer 4, and the p⁺-type contact layer 5, an ion implantation is performed by selecting an acceleration voltage of a predetermined value so that a peak of an impurity concentration is formed at a deep position.

Then, the photoresist 15a which is used as a mask is peeled off by oxygen plasma and the like. Then, a heat treatment is performed at 1000° C. or more to thermally diffuse the implanted ions.

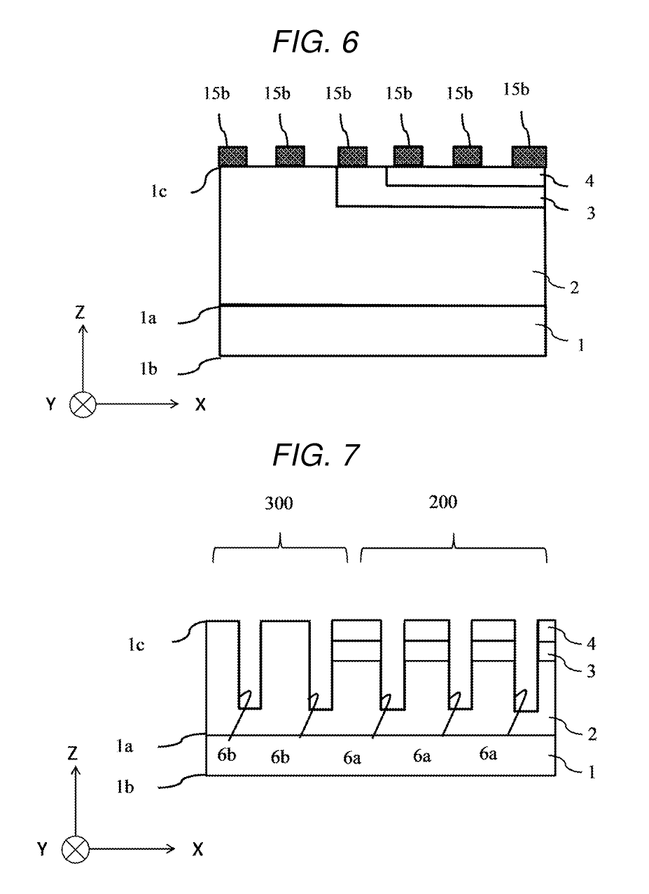

As illustrated in FIG. 6, a pattern for forming the trench 6a and the trench 6b in an oxide film is formed by applying a photoresist 15b on the third surface 1c and performing exposure and development on the photoresist 15b. This pattern has a width such that adjacent depletion layers are bonded, and is formed to have a width such that a flow of electrons is not inhibited when the MOSFET is in an on state.

As illustrated in FIG. 7, in order to form the trench 6a and the trench 6b by anisotropic etching, the n-type drift layer 2 is etched by, for example, Reactive Ion Etching (RIE) and the like. The RIE is an etching method to allow reactive gas such as freon (CF4) and the like to flow in a vacuum and to apply a high voltage thereto. Thereby, the reactive gas becomes plasma to be activated ions. The trenches 6a and 6b are formed by allowing the ions to collide toward the n-type drift layer 2. Then, the photoresist 15b is peeled off by oxygen plasma and the like.

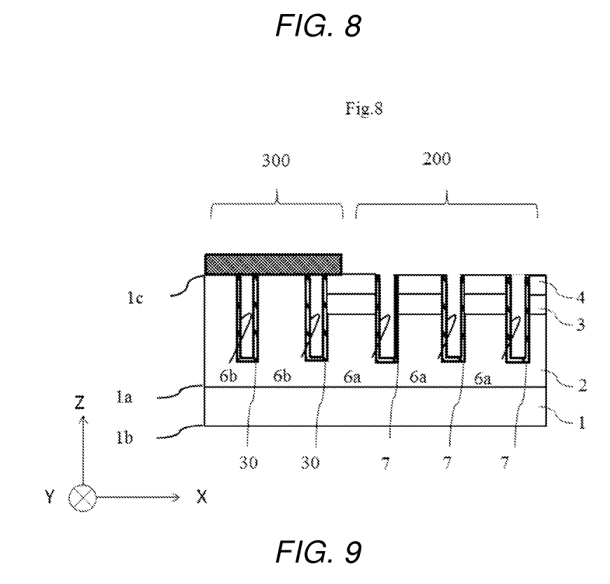

As illustrated in FIG. 8, a uniform first insulation film 7 is formed on a side wall and a bottom surface of the trench 6a and the trench 6b by performing heat oxidization at a substrate temperature of 1000° C. in a hydrogen atmosphere, an oxygen atmosphere, or the like. Then, a mask is formed in the trench 6b.

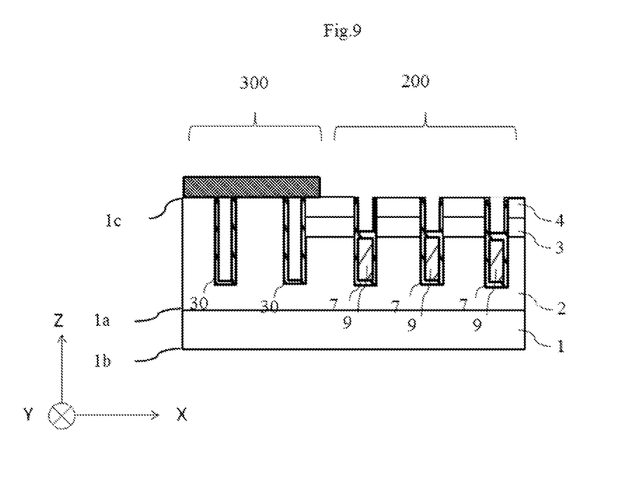

As illustrated in FIG. 9, the first field plate electrode 9 is formed in the trench 6a through the first insulation film 7. The first field plate electrode 9 is made of polysilicon. The polysilicon is formed by a CVD method and the like to achieve uniformity of a film. At this time, the first field plate electrode 9 is formed so as to be positioned in the n-type drift layer 2. Then, a uniform first insulation film 7 is formed on a side wall and a bottom surface of the trench 6a in which the first field plate electrode 9 is formed by performing heat oxidization at a substrate temperature of 1000° C. in a hydrogen atmosphere, an oxygen atmosphere, or the like.

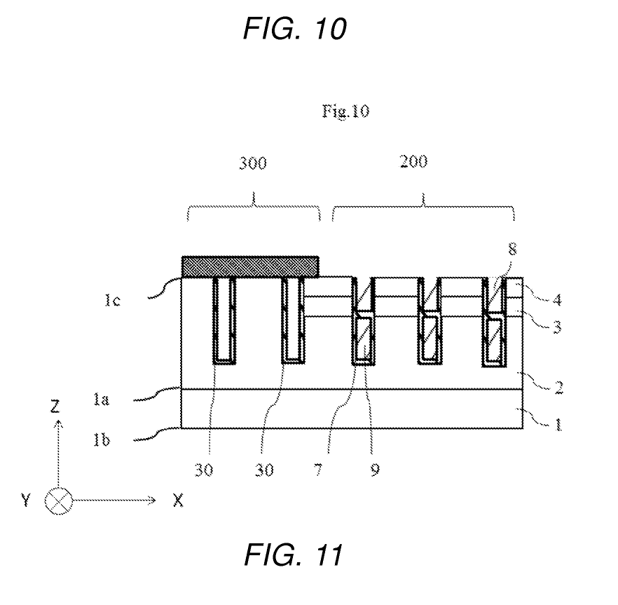

As illustrated in FIG. 10, the gate electrode 8 is formed through the first field plate electrode 9 and the first insulation film 7 in the trench 6a. The gate electrode 8 is formed through the first insulation film 7 so as to be positioned in the p-type base layer 3 and the n⁺-type source layer 4. The gate electrode 8 is made of a polysilicon. The polysilicon is formed by a CVD method and the like to achieve uniformity of a film.

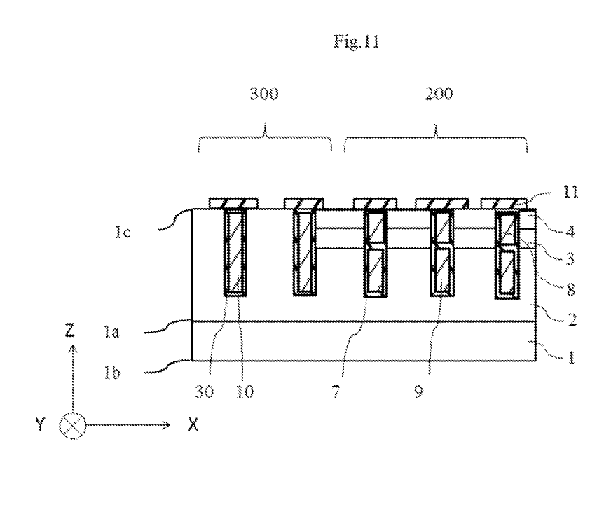

As illustrated in FIG. 11, an oxide silicon (SiO₂) is formed on the n-type drift layer 2 by, for example, a plasma CVD method and the like through the second insulation film 30 in the trench 6b. An SiO₂ with a raw material of tetraethoxysilane (TEOS) is formed on the third surface 1c by the CVD method. Then, an electrode is formed on the second surface 1b side and the third surface 1c side through the insulation film 11. The electrode is formed by, for example, sputtering or the like using a conductive material such as copper (Cu), aluminum, or the like.

In a manufacturing process according to the present embodiment, the trench 6a and the trench 6b are simultaneously formed using a mask formed such that adjacent depletion layers have a width of an extent that the adjacent layers are bonded together at an interval with which a flow of electrons is not inhibited. By forming the trench 6a and the trench 6b simultaneously with using the same mask, it is possible to form a trench having a width which is appropriate to bond adjacent depletion layers formed from field plate electrode and which does not generate an on-resistance. Time reduction in the manufacturing process of the semiconductor device 100 in which these effects may be obtained is possible as in the above description.

In the manufacturing method of the embodiment as described above, it is possible to manufacture the semiconductor device 100 which is capable of improving a breakdown voltage even with a simplified manufacturing process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer of a first conductivity type that includes a first region and a second region adjacent to the first region;
a second semiconductor layer of a second conductivity type that is provided on an upper side of the first semiconductor layer in the first region;
a third semiconductor layer of the first conductivity type that is provided on an upper side of the second semiconductor layer;
a first conductor that is provided in the first semiconductor layer through a first insulation film;
a second conductor that is provided in the second semiconductor layer and the third semiconductor layer side, and contacted with the first conductor, second semiconductor layer and the third semiconductor layer through the first insulation film:
a third conductor in the second region provided in the first semiconductor layer through a second insulation film in the direction from the third semiconductor layer to the first semiconductor layer; and
a first electrode in contact with an upper surface of the first semiconductor layer in the second region and an upper surface of the third semiconductor layer in the first region.

2. The device of claim 1,
wherein the first conductor and the third conductor are provided at regular intervals in a direction parallel to an interface between the first semiconductor layer and the second semiconductor layer.

3. The device of claim 1,
wherein a bottom surface of the first conductor and a bottom surface of the third conductor are at a same position in the direction from the third semiconductor layer to the first semiconductor layer.

4. The device of claim 1,
wherein an impurity concentration of the second semiconductor layer is increased in the direction from the third semiconductor layer to the first semiconductor layer.

5. The device of claim 4,
wherein the impurity concentration of the second semiconductor layer is 1×10¹⁶ cm⁻³ to 1×10¹⁸ cm⁻³.

6. The device of claim 1, further comprising
the first electrode, electrically connected to the first semiconductor layer, the second semiconductor layer, and the third semiconductor layer; and
a second electrode, in contact with a lower surface of the first semiconductor layer, and electrically connected to the first semiconductor layer.

7. The device of claim 6,
wherein an impurity concentration of the first semiconductor layer is increased in a direction from the semiconductor layer to the second electrode.

8. The device of claim 7,
wherein the impurity concentration of the first semiconductor layer is 1×10¹⁶ cm⁻³ to 1×10¹⁷ cm⁻³.

9. The device of claim 1,
wherein a material for the first conductor and the third conductor is silicon oxide or polysilicon.

10. A method of manufacturing a semiconductor device, comprising:
forming a first semiconductor layer of a first conductivity type that includes a first region and a second region;
forming a second semiconductor layer of a second conductivity type on an upper side of the first semiconductor layer in the first region;
forming a third semiconductor layer of the first conductivity type on an upper side of the second semiconductor layer;
forming one or more first trenches in the first region and one or more second trenches in the second region, the one or more first trenches in the first region extending through the first semiconductor layer, the second semiconductor layer and the third semiconductor layer, and the one or more second trenches in the second region extending through the first semiconductor layer;
forming a first conductor in each of the one or more first trenches in the first semiconductor layer through a first insulation film;
forming a second conductor in each of the one or more first trenches in the second semiconductor layer and the third semiconductor layer through the first insulation film;
forming a third conductor in each of the one or more second trenches through a second insulation film; and
forming a first electrode in contact with an upper surface of the first semiconductor layer in the second region and an upper surface of the third semiconductor layer in the first region.

11. The method of claim 11, further comprising:
forming the first electrode so as to be electrically connected to the first semiconductor layer, the second semiconductor layer, and the third semiconductor layer; and
forming a second electrode in contact with a lower surface of the first semiconductor layer and so as to be electrically connected to the first semiconductor layer.

12. The method of claim 11, further comprising:
forming the first conductor further into the first semiconductor layer of the one or more first trenches than the second conductor.
